(19) United States
(12) Patent Application Publication
(10) Pub. No.: US 2025/0318166 A1
(43) Pub. Date: Oct. 9, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yoko IWAKAJI, Meguro Tokyo (JP); Tomoko MATSUDAI, Shibuya Tokyo (JP); Keiko KAWAMURA, Yokohama Kanagawa (JP)

(21) Appl. No.: 18/822,449

(22) Filed: Sep. 2, 2024

(30) Foreign Application Priority Data
Apr. 5, 2024 (JP) 2024-061319

(51) Int. Cl. H01L 29/739; H01L 23/528; H01L 27/088; H01L 29/423

(52) U.S. Cl. CPC H10D 12/481; H01L 23/5286; H10D 64/513; H10D 84/83

(57) ABSTRACT

According to one embodiment, a semiconductor device includes a semiconductor layer with a plurality of first and second trenches extending lengthwise in a first direction. A first gate electrode is in each first trench. A second gate electrode is in each second trench. A first gate wiring has an upper metal layer and a lower metal layer and a second gate wiring also has an upper metal layer and a lower metal layer. At position where the first gate wiring and the second gate wiring cross without being electrically connected, the lower metal layer of one the first or second gate wirings and the upper metal layer of the other of the first or second gate wirings are not present.

### CROSS-REFERENCE TO RELATED APPLICATION

This application is based upon and claims the benefit of priority from Japanese Patent Application No. 2024-061319, filed Apr. 5, 2024, the entire contents of which are incorporated herein by reference.

### FIELD

Embodiments described herein relate generally to a semiconductor device.

### BACKGROUND

An insulated gate bipolar transistor (IGBT) is an example of a semiconductor device used for power-related applications. An IGBT may include a p-type collector region, an n-type drift region, and a p-type base region on a collector electrode. A gate electrode is provided in a trench that penetrates the p-type base region and reaches the n-type drift region with a gate insulating film interposed therebetween. An n-type emitter region can be connected to an emitter electrode provided in a region adjacent to the trench at a surface of the p-type base region.

In an IGBT, a channel is formed in the p-type base region by applying a positive voltage at or above a threshold voltage to the gate electrode. Then, electrons are injected from the n-type emitter region into the n-type drift region, and holes are injected from the collector region into the n-type drift region. Thereby, a current using electrons and holes as carriers flows between the collector electrode and the emitter electrode.

In an IGBT, it is desired to achieve both a reduction in on-resistance and a reduction in switching loss. In order to achieve both a reduction in on-resistance and switching loss, an IGBT that drives a plurality of gates independently of each other has been proposed. By changing drive timing of individual gates in the plurality, switching time of the IGBT can be shortened and switching losses can be reduced.

In an IGBT in which multiple gates of are driven independently of each other, a plurality of gate wirings connected to a plurality of gate electrode pads must be provided. The plurality of gate wirings are connected to the gate electrodes of different gates, respectively. In a case where an electrical resistance of the gate wiring is high, a wiring delay in the transmitted signal (switching voltage) occurs, and for example, it is difficult to speed up the switching operation of the IGBT. Therefore, it is desirable to reduce the electrical resistance of the gate wiring.

### BRIEF DESCRIPTION OF THE DRAWINGS

FIGS. 1A and 1B are schematic views of semiconductor device according to a first embodiment.

FIG. 2 is a schematic cross-sectional view of a semiconductor device of a first embodiment.

FIG. 3 is a schematic top view of a semiconductor device of a first embodiment.

FIGS. 4A and 4B are schematic views of a part of a semiconductor device of a first embodiment.

FIG. 5 is a schematic cross-sectional view of a part of a semiconductor device of a first embodiment.

FIGS. 6A and 6B are schematic views of a semiconductor device of a first embodiment.

FIG. 7 is a schematic cross-sectional view of a part of a semiconductor device of a first embodiment.

FIG. 8 is a schematic view of a semiconductor device according to a comparative example.

FIGS. 9A and 9B are schematic views of a semiconductor device of a first modification example of a first embodiment.

FIG. 10 is a schematic cross-sectional view of a part of a semiconductor device according to a first modification example of a first embodiment.

FIGS. 11A and 11B are schematic views of a semiconductor device of a second modification example of a first embodiment.

FIGS. 12A and 12B are schematic views of a semiconductor device of a second modification example of a first embodiment.

FIGS. 13A and 13B are schematic views of a semiconductor device of a third modification example of a first embodiment.

FIGS. 14A and 14B are schematic views of a semiconductor device of a third modification example of a first embodiment.

FIGS. 15A and 15B are schematic views of a semiconductor device of a second embodiment.

FIGS. 16A and 16B are a schematic view of a part of a semiconductor device of a second embodiment.

FIG. 17 is a schematic cross-sectional view of a part of a semiconductor device of a second embodiment.

FIGS. 18A and 18B are schematic views of a semiconductor device of a second embodiment.

FIG. 19 is a schematic cross-sectional view of a part of a semiconductor device of a first modification example of a second embodiment.

### DETAILED DESCRIPTION

Embodiments provide a semiconductor device capable of reducing an electric resistance in a gate wiring.

In general, according to one embodiment, a semiconductor device includes a semiconductor layer having a first surface and a second surface opposite the first surface. A plurality of first trenches extend into the semiconductor layer from a first surface side and extend lengthwise in a first direction parallel to the first surface. A plurality of second trenches extend into the semiconductor layer from the first surface side and extend lengthwise in the first direction. A first electrode is on the first surface side of the semiconductor layer. A second electrode is on a second surface side of the semiconductor layer. A first gate electrode is in each first trench, a second gate electrode is in each second trench. A first gate wiring is on the first surface side of the semiconductor layer and electrically connected to the first gate electrode. The first gate wiring includes a first upper metal layer and a first lower metal layer. The first lower metal layer is between the first upper metal layer and the first surface. A first portion of the first gate wiring extends in a second direction perpendicular to the first direction and parallel to the first surface. A second portion of the first gate wiring also extends in the second direction. The first electrode is between the first portion and the second portion. A second gate wiring is on the first surface side of the semiconductor layer and is electrically connected to the second gate electrode. The second gate wiring includes a second upper metal layer and a second lower metal layer. The second lower metal layer is between the second upper metal layer and the first surface. A third portion of the second gate wiring extends in the second direction. A fourth portion of the second gate wiring also extends in the second direction. The first electrode is between the third portion and the fourth portion. A first gate electrode pad is on the first surface side of the semiconductor layer and electrically connected to the first gate wiring. A second gate electrode pad is on the first surface side of the semiconductor layer and electrically connected to the second gate wiring. The first portion of the first gate wiring is between the first electrode and the third portion of the second gate wiring. The second portion of the first gate wiring is between the first electrode and the fourth portion of the second gate wiring. The first gate wiring and the second gate wiring cross at a first position, however, at the first position, the first lower metal layer and the second upper metal layer are not present or the first upper metal layer and the second lower metal layer are not present so as to prevent an unwanted electrical connection between first and second gate wirings.

Hereinafter, certain example embodiments of the present disclosure will be described with reference to the drawings. In the following description, the same reference symbols are given to those aspects that are the same or substantially similar to those already described in conjunction with another drawing, and the repeated description thereof may be omitted.

In the present specification, the notations of n⁺-type, n-type, and n⁻-type may be used, to indicate a relative impurity (dopant) concentration of the n-type. Similarly, the notations of p⁺-type, p-type, and p⁻type may be used to indicate a relative impurity (dopant) concentration of the p-type. Such concentration levels may be net or effective impurity concentration levels.

### First Embodiment

A semiconductor device of a first embodiment includes a semiconductor layer having a first surface and a second surface facing the first surface and including a plurality of first trenches provided on a first surface side and extending in a first direction parallel to the first surface, and a plurality of second trenches provided on the first surface side and extending in the first direction, a first electrode provided on the first surface side of the semiconductor layer, second electrode provided on a second surface side of the semiconductor layer, a first gate electrode provided in the first trench, a second gate electrode provided in the second trench, a first gate wiring provided on the first surface side of the semiconductor layer, including a first upper metal layer and a first lower metal layer provided between the first upper metal layer and the first surface, including a first portion extending in a second direction parallel to the first surface and perpendicular to the first direction and a second portion extending in the second direction and having the first electrode provided between the first portion and the second portion, and electrically connected to the first gate electrode, a second gate wiring provided on the first surface side of the semiconductor layer, including a second upper metal layer and a second lower metal layer provided between the second upper metal layer and the first surface, including a third portion extending in the second direction and a fourth portion extending in the second direction and having the first electrode provided between the third portion and the fourth portion, and electrically connected to the second gate electrode, a first gate electrode pad provided on the first surface side of the semiconductor layer and electrically connected to the first gate wiring, and a second gate electrode pad provided on the first surface side of the semiconductor layer and electrically connected to the second gate wiring. The first portion is provided between the third portion and the first electrode, and the second portion is provided between the fourth portion and the first electrode. The first gate wiring and the second gate wiring intersect at a first intersecting part. At the first intersecting part, either the first lower metal layer and the second upper metal layer are not present or the first upper metal layer and the second lower metal layer are not present.

The semiconductor device of the first embodiment is a trench-gate type IGBT 100 including a gate electrode in a trench formed in a semiconductor layer. The IGBT 100 is an IGBT having three gates that can be controlled independently and can be driven as a triple gate IGBT.

The IGBT 100 of the first embodiment includes a semiconductor layer 10, a first gate wiring 11, a second gate wiring 12, a third gate wiring 13, a first contact part 16, a second contact part 17, a third contact part 18, an emitter electrode 21 (first electrode), a collector electrode 22 (second electrode), a gate insulating film 23, a first gate electrode 31, a second gate electrode 32, a third gate electrode 33, a first interlayer insulating layer 36, a second interlayer insulating layer 37 (insulating layer), a first gate electrode pad 101, a second gate electrode pad 102, and a third gate electrode pad 103.

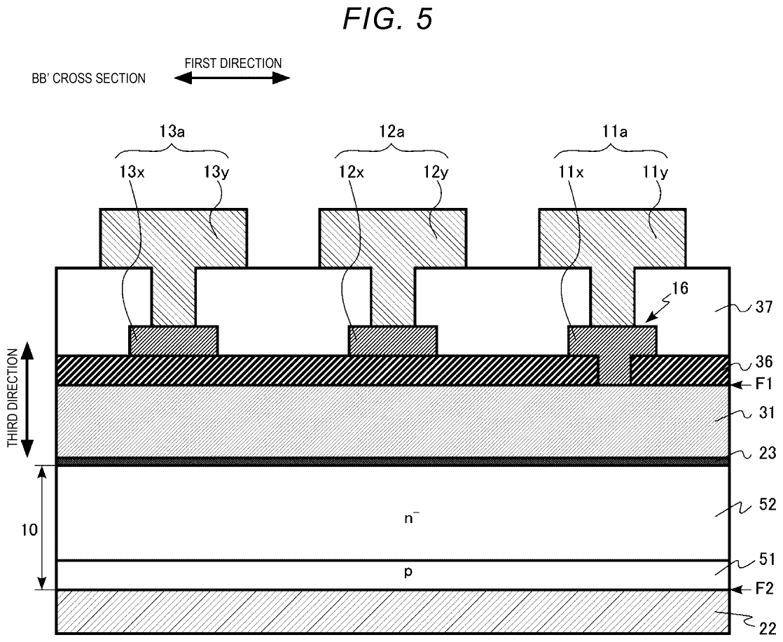

The first gate wiring 11 includes a first portion 11a and a second portion 11b. The first gate wiring 11 includes a first lower metal layer 11x and a first upper metal layer 11y (see FIG. 5).

The second gate wiring 12 includes a third portion 12a and a fourth portion 12b. The second gate wiring 12 includes a second lower metal layer 12x and a second upper metal layer 12y (see FIG. 5).

The third gate wiring 13 includes a fifth portion 13a and a sixth portion 13b. The third gate wiring 13 includes a third lower metal layer 13x and a third upper metal layer 13y (see FIG. 5).

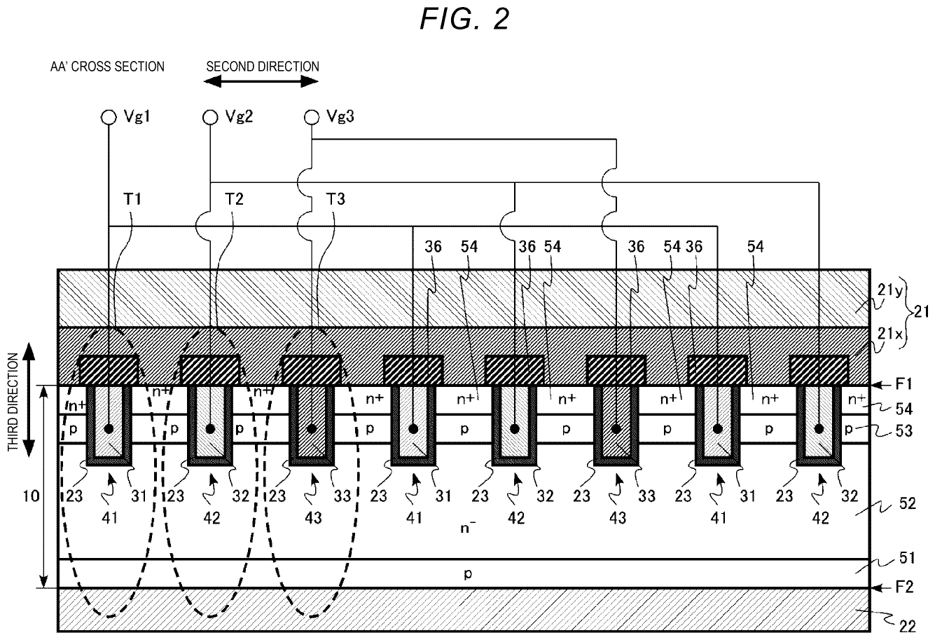

The emitter electrode 21 includes a fourth lower metal layer 21x and a fourth upper metal layer 21y (see FIG. 2).

A first gate trench 41 (first trench), a second gate trench 42 (second trench), a third gate trench 43 (third trench), a collector region 51, a drift region 52, a base region 53, an emitter region 54, and a contact region 55 are provided in the semiconductor layer 10.

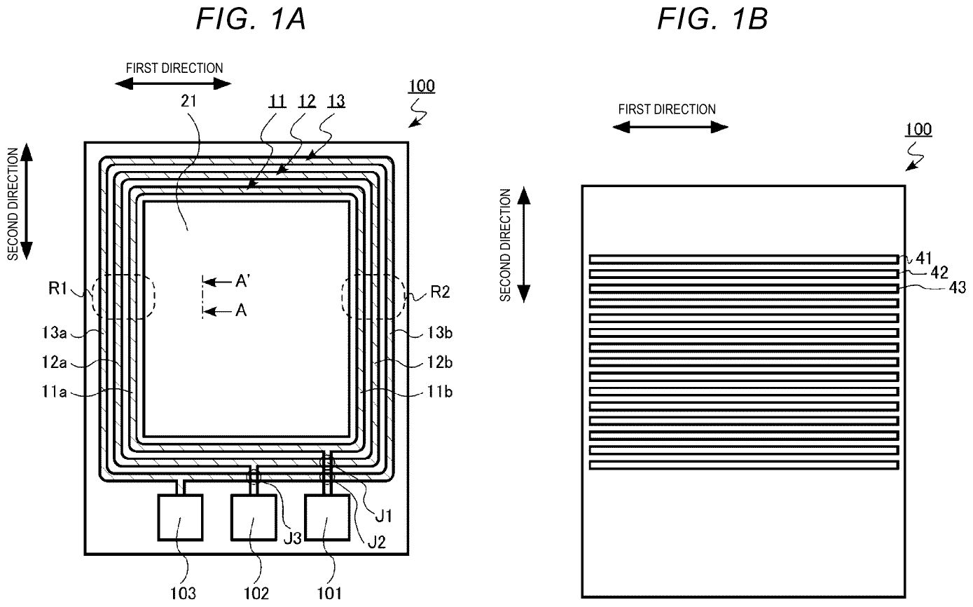

FIGS. 1A and 1B are schematic views of the semiconductor device according to the first embodiment. FIG. 1A shows a layout pattern of the first gate wiring 11, the second gate wiring 12, the third gate wiring 13, the first gate electrode pad 101, the second gate electrode pad 102, the third gate electrode pad 103, and the emitter electrode 21. FIG. 1B shows a layout pattern of the first gate trench 41, the second gate trench 42, and the third gate trench 43.

As shown in FIG. 1A, the first gate wiring 11 is connected to the first gate electrode pad 101. The first gate wiring 11 is electrically and physically connected to the first gate electrode pad 101. The first portion 11a of the first gate wiring 11 extends in the second direction. The second portion 11b of the first gate wiring 11 extends in the second direction. The emitter electrode 21 is provided between the first portion 11a and the second portion 11b. The first gate wiring 11 surrounds the emitter electrode 21.

As shown in FIG. 1A, the second gate wiring 12 is connected to the second gate electrode pad 102. The second gate wiring 12 is electrically and physically connected to the second gate electrode pad 102. The third portion 12a of the second gate wiring 12 extends in the second direction. The fourth portion 12b of the second gate wiring 12 extends in the second direction. The emitter electrode 21 is provided between the third portion 12a and the fourth portion 12b. The second gate wiring 12 surrounds the emitter electrode 21.

The first portion 11a of the first gate wiring 11 is provided between the third portion 12a of the second gate wiring 12 and the emitter electrode 21. The second portion 11b of the first gate wiring 11 is provided between the fourth portion 12b of the second gate wiring 12 and the emitter electrode 21.

As shown in FIG. 1A, the third gate wiring 13 is connected to the third gate electrode pad 103. The third gate wiring 13 is electrically and physically connected to the third gate electrode pad 103. The fifth portion 13a of the third gate wiring 13 extends in the second direction. The sixth portion 13b of the third gate wiring 13 extends in the second direction. The emitter electrode 21 is provided between the fifth portion 13a and the sixth portion 13b. The third gate wiring 13 surrounds the emitter electrode 21.

The third portion 12a of the second gate wiring 12 is provided between the fifth portion 13a of the third gate wiring 13 and the emitter electrode 21. The fourth portion 12b of the second gate wiring 12 is provided between the sixth portion 13b of the third gate wiring 13 and the emitter electrode 21.

The first gate wiring 11 and the second gate wiring 12 intersect at a first intersecting part J1. The first gate wiring 11 and the third gate wiring 13 intersect at a second intersecting part J2. The second gate wiring 12 and the third gate wiring 13 intersect at a third intersecting part J3.

As shown in FIG. 1B, the first gate trench 41, the second gate trench 42, and the third gate trench 43 extend longitudinally (lengthwise) in the first direction.

FIG. 2 is a schematic cross-sectional view of the semiconductor device of the first embodiment. FIG. 2 is a cross-sectional view taken along the line AA′ of FIG. 1A. FIG. 2 is a cross-sectional view including the emitter electrode 21.

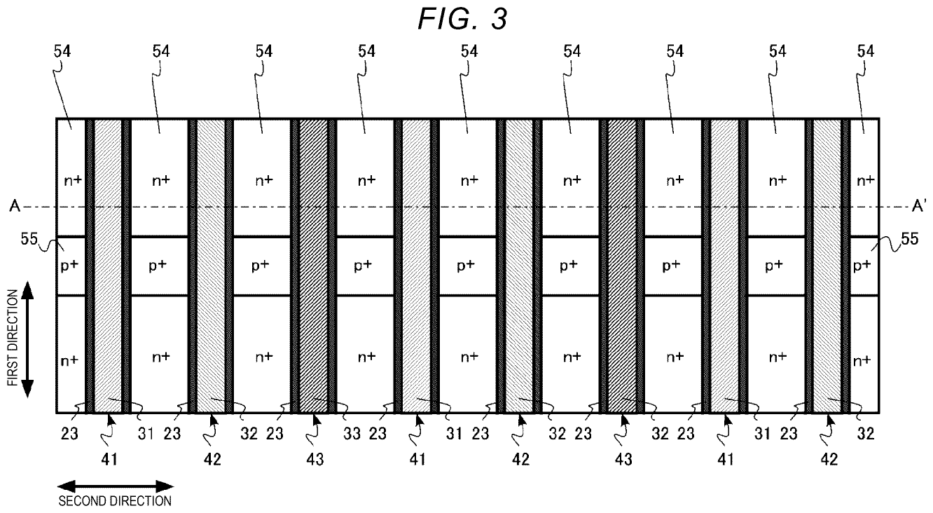

FIG. 3 is a schematic top view of the semiconductor device of the first embodiment. FIG. 3 is a top view of the first surface F1. FIG. 2 is a cross-sectional view taken along the line AA′ of FIG. 3.

The semiconductor layer 10 has the first surface F1 and a second surface F2 facing the first surface F1. The semiconductor layer 10 is, for example, single crystal silicon (monocrystalline silicon).

In the present description, one direction parallel to the first surface F1 is referred to as a first direction. Another direction parallel to the first surface F1 but perpendicular to the first direction is referred to as a second direction. The direction orthogonal (normal) to the first surface F1 is referred to as a third direction.

The emitter electrode 21 is provided on a first surface F1 side of the semiconductor layer 10. At least a part of the emitter electrode 21 is in contact with the first surface F1 of the semiconductor layer 10.

The emitter electrode 21 is made of metal. The emitter electrode 21 includes the fourth lower metal layer 21x and the fourth upper metal layer 21y. The fourth lower metal layer 21x is provided between the fourth upper metal layer 21y and the first surface F1.

The fourth lower metal layer 21x is formed of a first material. The first material is a metal. The fourth upper metal layer 21y is formed of a second material. The second material is a metal.

The first material and the second material are different metals. The first material is or comprises, for example, tungsten (W), molybdenum (Mo), or tantalum (Ta). The second material is or comprises, for example, aluminum (Al) or copper (Cu).

The fourth lower metal layer 21x can be, for example, a stacked film of titanium, titanium nitride, and tungsten. In addition, the fourth upper metal layer 21y can be, for example, a stacked film of titanium, titanium nitride, and aluminum.

The fourth lower metal layer 21x and the fourth upper metal layer 21y are electrically and physically connected to each other. An insulating layer may be provided in certain parts or regions between the fourth lower metal layer 21x and the fourth upper metal layer 21y.

The emitter electrode is electrically connected to the emitter region 54 and the contact region 55. An emitter voltage is applied to the emitter electrode 21. The emitter voltage is, for example, 0 V.

The collector electrode 22 is provided on a second surface F2 side of the semiconductor layer 10. At least a part of the collector electrode 22 is in contact with the second surface F2 of the semiconductor layer 10. The collector electrode 22 is, for example, a metal.

The collector electrode 22 is electrically connected to the p-type collector region 51. A collector voltage is applied to the collector electrode 22. The collector voltage is, for example, 200 V to 6500 V.

The collector region 51 is a p-type semiconductor region. The collector region 51 is electrically connected to the collector electrode 22. The collector region 51 is in contact with the collector electrode 22. The collector region 51 serves as a supply source of a hole in a case where the IGBT 100 is in an on-state.

The drift region 52 is a semiconductor region of an n⁻-type. The drift region 52 is provided between the collector region 51 and the first surface F1. The drift region 52 is a path of an on-current in a case where the IGBT 100 is in an on-state. The drift region 52 is depleted in a case where the IGBT 100 is in an off-state and has a function of maintaining the breakdown voltage of the IGBT 100.

The base region 53 is a p-type semiconductor region. The base region 53 is provided between the drift region 52 and the first surface F1. The base region 53 functions as a channel region of a transistor.

The emitter region 54 is an n⁺-type semiconductor region. The emitter region 54 is provided between the base region 53 and the first surface F1. The emitter region 54 is electrically connected to the emitter electrode 21. The emitter region 54 is in contact with the emitter electrode 21. The emitter region 54 serves as a supply source of an electron in a case where the transistor is in the on-state.

The contact region 55 is a p⁺-type semiconductor region. The contact region 55 is provided between the base region 53 and the first surface F1. The contact region 55 is provided adjacent to or separated from the emitter region 54. The contact region 55 is electrically connected to the emitter electrode 21.

A plurality of first gate trenches 41 are provided on the first surface F1 side of the semiconductor layer 10. As shown in FIG. 3, the first gate trench 41 extends in the first direction parallel to the first surface F1 on the first surface F1. The first gate trench 41 has a stripe shape. The plurality of first gate trenches 41 are repeatedly disposed in the second direction orthogonal to the first direction. The first gate trench 41 penetrates the base region 53 and reaches the drift region 52.

A plurality of second gate trenches 42 are provided on the first surface F1 side of the semiconductor layer 10. The second gate trench 42 extends in the first direction on the first surface F1 as shown in FIG. 3. The second gate trench 42 has a stripe shape. The second gate trench 42 is repeatedly disposed in the second direction. The second gate trench 42 penetrates the base region 53 and reaches the drift region 52.

A plurality of third gate trenches 43 are provided on the first surface F1 side of the semiconductor layer 10. The third gate trench 43 extends in the first direction on the first surface F1 as shown in FIG. 3. The third gate trench 43 has a stripe shape. The third gate trench 43 is repeatedly disposed in the second direction. The third gate trench 43 penetrates the base region 53 and reaches the drift region 52.

The first gate electrode 31 is provided in the first gate trench 41. The first gate electrode 31 is, for example, a semiconductor or a metal. The first gate electrode 31 is, for example, polycrystalline silicon containing a conductive impurity. The first gate electrode 31 is electrically connected to the first gate wiring 11 and the first gate electrode pad 101.

The second gate electrode 32 is provided in the second gate trench 42. The second gate electrode 32 is, for example, a semiconductor or a metal. The second gate electrode 32 is, for example, polycrystalline silicon containing a conductive impurity. The second gate electrode 32 is electrically connected to the second gate wiring 12 and the second gate electrode pad 102.

The third gate electrode 33 is provided in the third gate trench 43. The third gate electrode 33 is, for example, a semiconductor or a metal. The third gate electrode 33 is, for example, polycrystalline silicon containing a conductive impurity. The third gate electrode 33 is electrically connected to the third gate wiring 13 and the third gate electrode pad 103.

The gate insulating film 23 is provided between the first gate electrode 31 and the semiconductor layer 10. The gate insulating film 23 is provided between the second gate electrode 32 and the semiconductor layer 10. The gate insulating film 23 is provided between the third gate electrode 33 and the semiconductor layer 10. The gate insulating film 23 is, for example, silicon oxide.

The first interlayer insulating layer 36 is provided between the first gate electrode 31 and the emitter electrode 21. The first interlayer insulating layer 36 electrically separates the first gate electrode 31 from the emitter electrode 21.

The first interlayer insulating layer 36 is provided between the second gate electrode 32 and the emitter electrode 21. The first interlayer insulating layer 36 electrically separates the second gate electrode 32 from the emitter electrode 21.

The first interlayer insulating layer 36 is provided between the third gate electrode 33 and the emitter electrode 21. The first interlayer insulating layer 36 electrically separates the third gate electrode 33 from the emitter electrode 21.

The first interlayer insulating layer 36 is, for example, a silicon oxide.

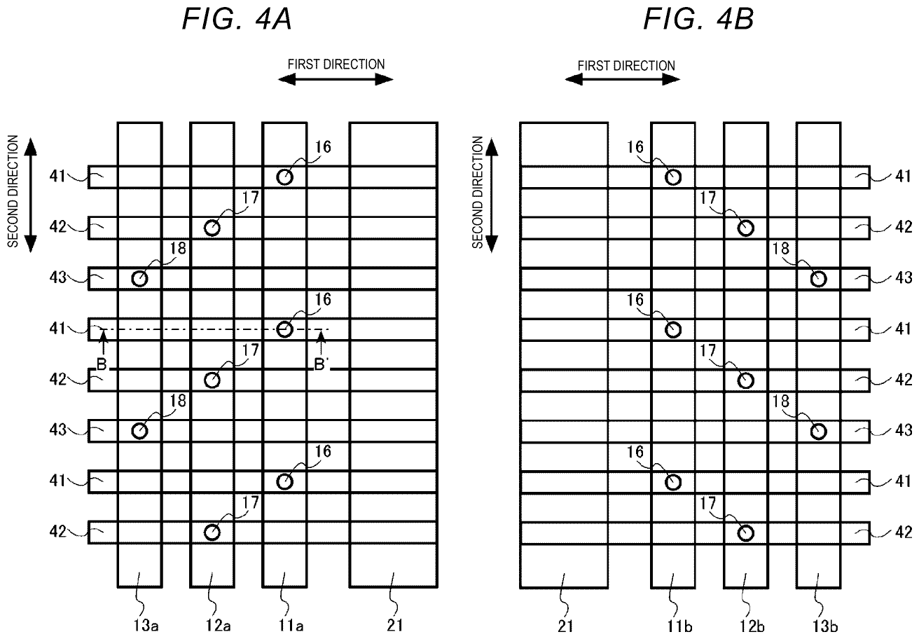

FIGS. 4A and 4B are schematic views of a part of the semiconductor device of the first embodiment. FIG. 4A is an enlarged view of a first region R1 shown in FIG. 1A. FIG. 4B is an enlarged view of a second region R2 shown in FIG. 1A.

FIGS. 4A and 4B show layout patterns of the first gate wiring 11, the second gate wiring 12, the third gate wiring 13, the first contact part 16, the second contact part 17, the third contact part 18, and the emitter electrode 21.

As shown in FIG. 4A, the first contact part 16 is provided at a position where the first portion 11a of the first gate wiring 11 and the first gate trench 41 intersect. At the first contact part 16, the first portion 11a is electrically and physically connected to the first gate electrode 31 provided in the first gate trench 41.

As shown in FIG. 4A, the second contact part 17 is provided at a position where the third portion 12a of the second gate wiring 12 and the second gate trench 42 intersect. At the second contact part 17, the third portion 12a is electrically and physically connected to the second gate electrode 32 provided in the second gate trench 42.

As shown in FIG. 4A, the third contact part 18 is provided at a position where the fifth portion 13a of the third gate wiring 13 and the third gate trench 43 intersect. At the third contact part 18, the fifth portion 13a is electrically and physically connected to the third gate electrode 33 provided in the third gate trench 43.

As shown in FIG. 4B, the first contact part 16 is provided at a position where the second portion 11b of the first gate wiring 11 and the first gate trench 41 intersect. At the first contact part 16, the second portion 11b is electrically and physically connected to the first gate electrode 31 provided in the first gate trench 41.

As shown in FIG. 4B, the second contact part 17 is provided at a position where the fourth portion 12b of the second gate wiring 12 and the second gate trench 42 intersect. At the second contact part 17, the fourth portion 12b is electrically and physically connected to the second gate electrode 32 provided in the second gate trench 42.

As shown in FIG. 4B, the third contact part 18 is provided at a position where the sixth portion 13b of the third gate wiring 13 and the third gate trench 43 intersect. At the third contact part 18, the sixth portion 13b is electrically and physically connected to the third gate electrode 33 provided in the third gate trench 43.

FIG. 5 is a schematic cross-sectional view of a part of the semiconductor device of the first embodiment. FIG. 5 is a cross-sectional view taken along the line BB′ of FIG. 4A.

The first gate wiring 11 is made of metal. The first gate wiring 11 includes the first lower metal layer 11x and the first upper metal layer 11y. The first lower metal layer 11x is provided between the first upper metal layer 11y and the first surface F1.

The second gate wiring 12 is made of a metal. The second gate wiring 12 includes the second lower metal layer 12x and the second upper metal layer 12y. The second lower metal layer 12x is provided between the second upper metal layer 12y and the first surface F1.

The third gate wiring 13 is made of a metal. The third gate wiring 13 includes the third lower metal layer 13x and the third upper metal layer 13y. The third lower metal layer 13x is provided between the third upper metal layer 13y and the first surface F1.

The first lower metal layer 11x, the second lower metal layer 12x, and the third lower metal layer 13x are formed of the first material. The first material is a metal. The first material of the first lower metal layer 11x, the second lower metal layer 12x, and the third lower metal layer 13x is the same as the first material of the fourth lower metal layer 21x of the emitter electrode 21.

The first upper metal layer 11y, the second upper metal layer 12y, and the third upper metal layer 13y are formed of the second material. The second material is a metal. The second material of the first upper metal layer 11y, the second upper metal layer 12y, and the third upper metal layer 13y is the same as the second material of the fourth upper metal layer 21y of the emitter electrode 21.

The first material and the second material are different metals. The first material is or comprises, for example, tungsten (W), molybdenum (Mo), or tantalum (Ta). The second material is or comprises, for example, aluminum (Al) or copper (Cu).

The first lower metal layer 11x, the second lower metal layer 12x, and the third lower metal layer 13x can be, for example, a stacked film of titanium, titanium nitride, and tungsten.

The first upper metal layer 11y, the second upper metal layer 12y, and the third upper metal layer 13y can be, for example, a stacked film of titanium, titanium nitride, and aluminum.

The first lower metal layer 11x, the second lower metal layer 12x, and the third lower metal layer 13x are electrically and physically connected to the first upper metal layer 11y, the second upper metal layer 12y, and the third upper metal layer 13y, respectively.

Each of the first gate wiring 11, the second gate wiring 12, and the third gate wiring 13 has a stacked structure including two different metal layers.

As shown in FIG. 5, the second interlayer insulating layer 37 is provided, for example, between a part of the first lower metal layer 11x and a part of the first upper metal layer 11y. The second interlayer insulating layer 37 is provided, for example, between a part of the second lower metal layer 12x and a part of the second upper metal layer 12y. The second interlayer insulating layer 37 is provided, for example, between a part of the third lower metal layer 13x and a part of the third upper metal layer 13y.

As shown in FIG. 5, the first lower metal layer 11x of the first gate wiring 11 is connected to the first gate electrode 31 at the first contact part 16.

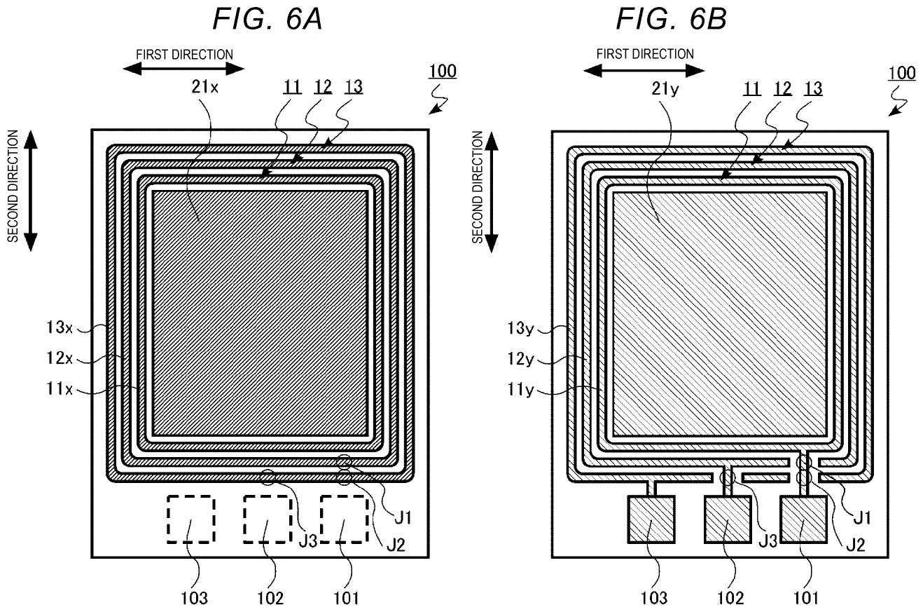

FIGS. 6A and 6B are schematic views of the semiconductor device of the first embodiment. FIG. 6A shows a layout pattern of the first lower metal layer 11x of the first gate wiring 11, the second lower metal layer 12x of the second gate wiring 12, the third lower metal layer 13x of the third gate wiring 13, and the fourth lower metal layer 21x of the emitter electrode 21. FIG. 6B shows a layout pattern of the first upper metal layer 11y of the first gate wiring 11, the second upper metal layer 12y of the second gate wiring 12, the third upper metal layer 13y of the third gate wiring 13, and the fourth upper metal layer 21y of the emitter electrode 21.

FIG. 6B also shows a layout pattern of the first gate electrode pad 101, the second gate electrode pad 102, and the third gate electrode pad 103, which are formed of the same second material as the first upper metal layer 11y, the second upper metal layer 12y, the third upper metal layer 13y, and the fourth upper metal layer 21y.

As shown in FIG. 6A, the first lower metal layer 11x surrounds the fourth lower metal layer 21x. The first lower metal layer 11x surrounds the emitter electrode 21. The first lower metal layer 11x is annular in a plane parallel to the first surface F1.

As shown in FIG. 6A, the second lower metal layer 12x surrounds the fourth lower metal layer 21x. The second lower metal layer 12x surrounds the emitter electrode 21. The second lower metal layer 12x surrounds the first lower metal layer 11x. The second lower metal layer 12x is annular in a plane parallel to the first surface F1.

As shown in FIG. 6A, the third lower metal layer 13x surrounds the fourth lower metal layer 21x. The third lower metal layer 13x surrounds the emitter electrode 21. The third lower metal layer 13x surrounds the second lower metal layer 12x. The third lower metal layer 13x is annular in a plane parallel to the first surface F1.

As shown in FIG. 6A, the first lower metal layer 11x is not present at the first intersecting part J1 between the first gate wiring 11 and the second gate wiring 12. That is, the first lower metal layer 11x is not at the junction/crossover of the first gate wiring 11 and the second gate wiring 12. Furthermore, as shown in FIG. 6B, the second upper metal layer 12y is not present at the first intersecting part J1. That is, the first lower metal layer 12y is not at the junction/crossover of the first gate wiring 11 and the second gate wiring 12.

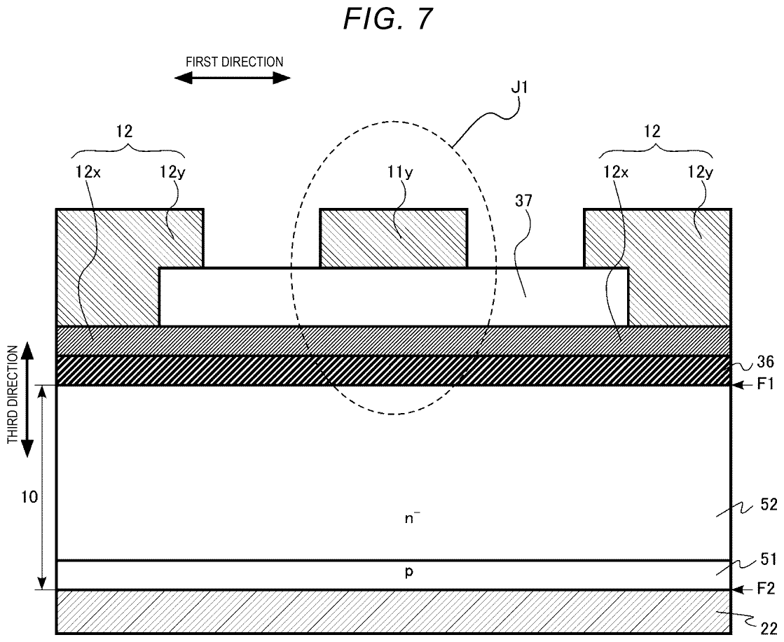

FIG. 7 is a schematic cross-sectional view of a part of the semiconductor device of the first embodiment. FIG. 7 is a cross section of the first intersecting part J1. FIG. 7 is a cross section parallel to the first direction and perpendicular to the second direction.

As shown in FIG. 7, at the first intersecting part J1, the second gate wiring 12 is continuous only in the second lower metal layer 12x of the second gate wiring in the first direction. In addition, at the first intersecting part J1, the first gate wiring 11 continuously extends in the second direction perpendicular to a paper surface only in the first upper metal layer 11y.

At the first intersecting part J1, the first gate wiring 11 and the second gate wiring 12 are separated from each other with the second interlayer insulating layer 37 interposed therebetween. Therefore, at the first intersecting part J1, the first gate wiring 11 and the second gate wiring 12 are not short-circuited.

As shown in FIG. 6A, the first lower metal layer 11x is not present at the second intersecting part J2 between the first gate wiring 11 and the third gate wiring 13. That is, the first lower metal layer 11x is not at the junction/crossover of the first gate wiring 11 and the third gate wiring 13. Furthermore, as shown in FIG. 6B, the second upper metal layer 12y is not present at the second intersecting part J2. That is, the first lower metal layer 12y is not at the junction/crossover of the first gate wiring 11 and the third gate wiring 12. Therefore, at the second intersecting part J2, the first gate wiring 11 and the third gate wiring 13 are not short-circuited.

As shown in FIG. 6A, the second lower metal layer 12x is not present at the third intersecting part J3 between the second gate wiring 12 and the third gate wiring 13. Further, as shown in FIG. 6B, the third upper metal layer 13y is not present at the third intersecting part J3. Therefore, the second gate wiring 12 and the third gate wiring 13 are not short-circuited to each other at the third intersecting part J3.

Next, an operation and an effect of the semiconductor device of the first embodiment will be described.

The IGBT 100 of the first embodiment includes the first gate electrode 31 to which a first gate voltage (Vg1) is applied, the second gate electrode 32 to which a second gate voltage (Vg2) is applied, and the third gate electrode 33 to which a third gate voltage (Vg3) is applied. The IGBT 100 of the first embodiment includes a first transistor controlled by the first gate electrode 31, a second transistor controlled by the second gate electrode 32, and a third transistor controlled by the third gate electrode 33. For example, a region surrounded by a broken line T1 in FIG. 2 corresponds to the first transistor. Further, for example, a region surrounded by a broken line T2 in FIG. 2 corresponds to the second transistor. Further, for example, a region surrounded by a broken line T3 in FIG. 2 corresponds to the third transistor. The triple gate driving of the IGBT 100 can be realized by providing independent gate signals to the first transistor, the second transistor, and the third transistor. The IGBT 100 can achieve both a reduction in on-resistance and a reduction in switching loss by the triple gate driving, for example.

In order to perform the triple gate driving, three gate electrode pads are required to apply three different gate voltages. Three gate wirings are required to connect each of the gate electrode pads to the gate electrode.

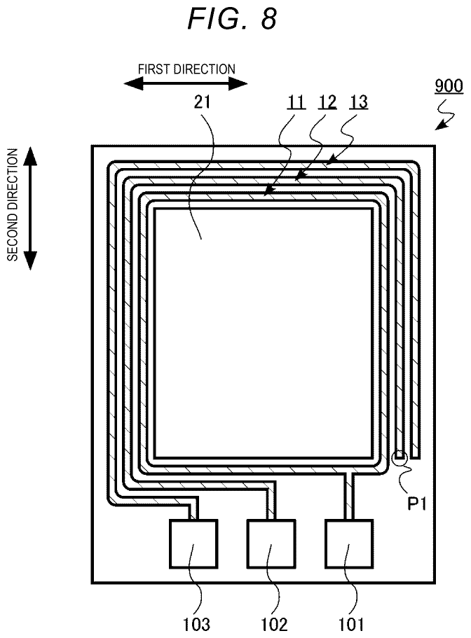

FIG. 8 is a schematic view of the semiconductor device according to the comparative example. FIG. 8 is a view corresponding to FIG. 1A of the first embodiment.

The semiconductor device of the comparative example is an IGBT 900 capable of triple gate driving. The IGBT 900 of the comparative example is different from the IGBT 100 of the first embodiment in that the first gate wiring 11, the second gate wiring 12, and the third gate wiring 13 are formed of a single-layer metal layer.

For example, in FIG. 8, a wiring length from an end portion (P1 in FIG. 8) of the second gate wiring 12 to the second gate electrode pad 102 is extremely long because the second gate wiring 12 winds around the emitter electrode 21. A wiring length from the second gate electrode pad 102 to the gate electrode connected to the second gate wiring 12 at the end portion P1 is increased. An electrical resistance of the second gate wiring 12 up to the end portion P1 increases. As a result, wiring delay to the gate electrode connected to the second gate wiring 12 at the end portion P1 is increased. Therefore, for example, it is difficult to speed up the operation of the IGBT 900.

In addition, since the first gate wiring 11, the second gate wiring 12, and the third gate wiring 13 of the IGBT 900 of the comparative example are formed of the single-layer metal layer, the electrical resistance per unit length of the gate wiring is also increased.

In the IGBT 100 of the first embodiment, each of the first gate wiring 11, the second gate wiring 12, and the third gate wiring 13 has a stacked structure with the first lower metal layer 11x and the first upper metal layer 11y, the second lower metal layer 12x and the second upper metal layer 12y, and the third lower metal layer 13x and the third upper metal layer 13y. Therefore, the electrical resistance per unit length of the gate wiring can be reduced.

Further, by forming the first gate wiring 11, the second gate wiring 12, and the third gate wiring 13 in a stacked structure, it is possible to intersect each of the gate wirings. The wiring length of the gate wiring from the electrode pad to the gate electrode can be shortened. Therefore, the electrical resistance of the gate wiring can be reduced.

According to the IGBT 100 of the first embodiment, for example, the operation of the IGBT 100 can be speeded up by reducing the electrical resistance of the gate wiring.

In addition, according to the IGBT 100 of the first embodiment, it is possible to intersect each of the gate wirings, so that the design freedom of the layout pattern of the gate wiring is increased. Therefore, for example, a chip size of the IGBT 100 can be reduced.

In addition, the first lower metal layer 11x, the second lower metal layer 12x, and the third lower metal layer 13x can be formed at the same time as the fourth lower metal layer 21x of the emitter electrode 21. In addition, the first upper metal layer 11y, the second upper metal layer 12y, and the third upper metal layer 13y can be formed at the same time as the fourth upper metal layer 21y of the emitter electrode 21. Therefore, an additional manufacturing step for forming a stacked structure of the gate wiring is not required, and an increase in manufacturing cost of the IGBT 100 can be prevented.

### First Modification Example

A semiconductor device according to a first modification example of the first embodiment is different from the semiconductor device according to the first embodiment in that a first upper metal layer of the second gate wiring surrounds the first electrode and a third upper metal layer of the third gate wiring surrounds the first electrode.

The semiconductor device according to the first modification example of the first embodiment is an IGBT 110.

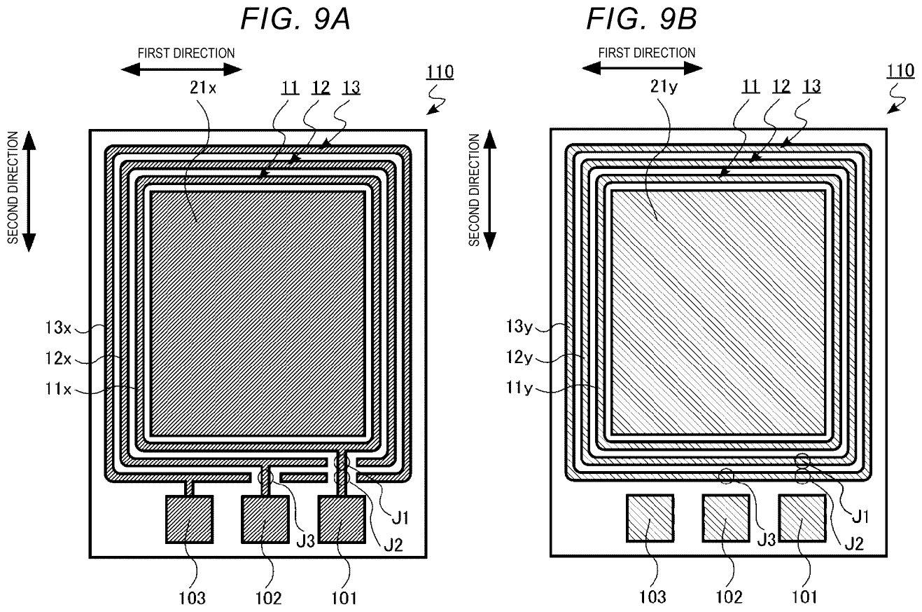

FIGS. 9A and 9B are schematic views of the semiconductor device according to the first modification example of the first embodiment. FIGS. 9A and 9B are views corresponding to FIGS. 6A and 6B of the first embodiment.

FIG. 9A shows a layout pattern of the first lower metal layer 11x of the first gate wiring 11, the second lower metal layer 12x of the second gate wiring 12, the third lower metal layer 13x of the third gate wiring 13, and the fourth lower metal layer 21x of the emitter electrode 21. FIG. 9B shows a layout pattern of the first upper metal layer 11y of the first gate wiring 11, the second upper metal layer 12y of the second gate wiring 12, the third upper metal layer 13y of the third gate wiring 13, and the fourth upper metal layer 21y of the emitter electrode 21.

FIG. 9A also shows a layout pattern of the first gate electrode pad 101, the second gate electrode pad 102, and the third gate electrode pad 103, which are formed of the same first material as the first lower metal layer 11x, the second lower metal layer 12x, the third lower metal layer 13x, and the fourth lower metal layer 21x.

In addition, FIG. 9B also shows a layout pattern of the first gate electrode pad 101, the second gate electrode pad 102, and the third gate electrode pad 103, which are formed of the same second material as the first upper metal layer 11y, the second upper metal layer 12y, the third upper metal layer 13y, and the fourth upper metal layer 21y.

As shown in FIG. 9B, the first upper metal layer 11y surrounds the fourth upper metal layer 21y. The first upper metal layer 11y surrounds the emitter electrode 21. The first upper metal layer 11y is annular in a plane parallel to the first surface F1.

As shown in FIG. 9B, the second upper metal layer 12y surrounds the fourth upper metal layer 21y. The second upper metal layer 12y surrounds the emitter electrode 21. The second upper metal layer 12y surrounds the first upper metal layer 11y. The second upper metal layer 12y is annular in a plane parallel to the first surface F1.

As shown in FIG. 9B, the third upper metal layer 13y surrounds the fourth upper metal layer 21y. The third upper metal layer 13y surrounds the emitter electrode 21. The third upper metal layer 13y surrounds the second upper metal layer 12y. The third upper metal layer 13y is annular in a plane parallel to the first surface F1.

As shown in FIG. 9A, the second lower metal layer 12x is not present at the first intersecting part J1 (crossover) between the first gate wiring 11 and the second gate wiring 12. Furthermore, as shown in FIG. 9B, the first upper metal layer 11y is not present at the first intersecting part J1.

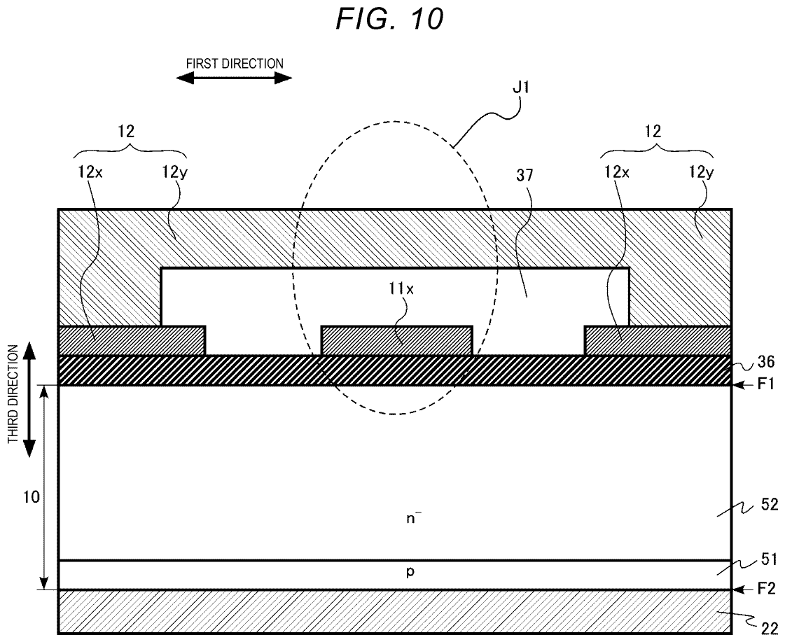

FIG. 10 is a schematic cross-sectional view of a part of the semiconductor device according to the first modification example of the first embodiment. FIG. 10 is a cross section of the first intersecting part J1. FIG. 10 is a cross section parallel to the first direction and perpendicular to the second direction.

As shown in FIG. 10, at the first intersecting part J1, the first gate wiring 11 continuously extends in the second direction only in the first lower metal layer 11x. In addition, at the first intersecting part J1, the second gate wiring 12 is continuous only in the second upper metal layer 12y in the first direction.

At the first intersecting part J1, the first gate wiring 11 and the second gate wiring 12 are separated from each other with the second interlayer insulating layer 37 interposed therebetween. Therefore, at the first intersecting part J1, the first gate wiring 11 and the second gate wiring 12 are not short-circuited.

As shown in FIG. 9A, the third lower metal layer 13x is not present at the second intersecting part J2 between the first gate wiring 11 and the third gate wiring 13. Furthermore, as shown in FIG. 9B, the first upper metal layer 11y is not present at the second intersecting part J2. Therefore, at the second intersecting part J2, the first gate wiring 11 and the third gate wiring 13 are not short-circuited.

As shown in FIG. 9A, the third lower metal layer 13x is not present at the third intersecting part J3 between the second gate wiring 12 and the third gate wiring 13. Furthermore, as shown in FIG. 9B, the second upper metal layer 12y is not present at the third intersecting part J3. Therefore, the second gate wiring 12 and the third gate wiring 13 are not short-circuited to each other at the third intersecting part J3.

According to the IGBT 110 of the first modification example of the first embodiment, the electrical resistance of the gate wiring can be reduced as in the IGBT 100 of the first embodiment.

### Second Modification Example

A semiconductor device according to a second modification example of the first embodiment is different from the semiconductor device of the first embodiment in that the first gate wiring includes a seventh portion provided between the first portion and the second portion and extending in the second direction, the second gate wiring includes an eighth portion provided between the third portion and the fourth portion and extending in the second direction, and the third gate wiring includes a ninth portion provided between the fifth portion and the sixth portion and extending in the second direction.

The semiconductor device according to the second modification example of the first embodiment is an IGBT 120.

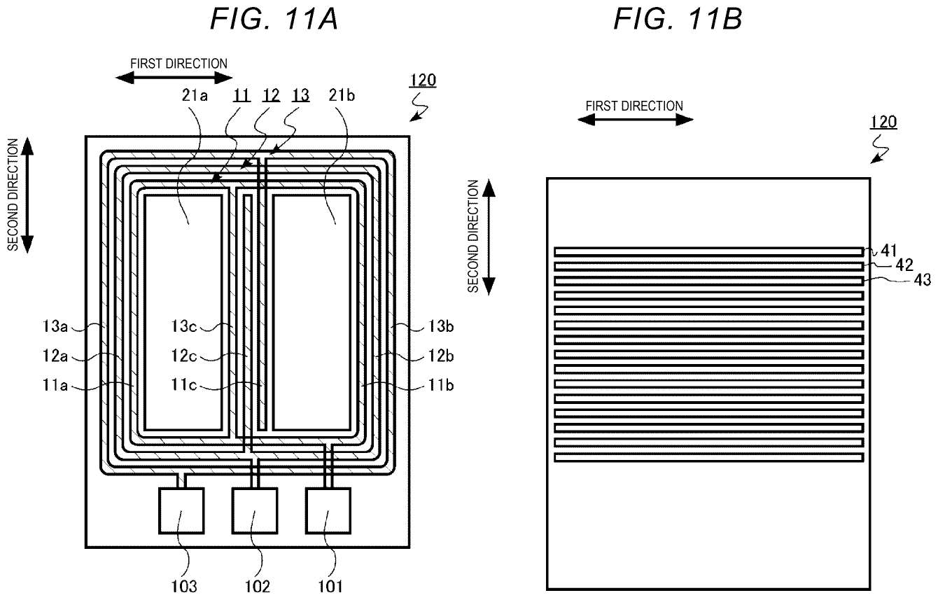

FIGS. 11A and 11B are schematic views of the semiconductor device according to the second modification example of the first embodiment. FIGS. 11A and 11B are views corresponding to FIGS. 1A and 1B of the first embodiment.

The first gate wiring 11, the second gate wiring 12, and the third gate wiring 13 include a seventh portion 11c, an eighth portion 12c, and a ninth portion 13c, respectively.

The emitter electrode 21 includes a first region 21a and a second region 21b divided in the second direction.

The seventh portion 11c of the first gate wiring 11 is provided between the first portion 11a and the second portion 11b. The seventh portion 11c of the first gate wiring 11 extends in the second direction. The first region 21a of the emitter electrode 21 is provided between the first portion 11a and the seventh portion 11c. The second region 21b of the emitter electrode 21 is provided between the second portion 11b and the seventh portion 11c.

The eighth portion 12c of the second gate wiring 12 is provided between the third portion 12a and the fourth portion 12b. The eighth portion 12c of the second gate wiring 12 extends in the second direction. The first region 21a of the emitter electrode 21 is provided between the third portion 12a and the eighth portion 21c. The second region 21b of the emitter electrode 21 is provided between the fourth portion 12b and the eighth portion 12c.

The ninth portion 13c of the third gate wiring 13 is provided between the fifth portion 13a and the sixth portion 13b. The ninth portion 13c of the third gate wiring 13 extends in the second direction. The first region 21a of the emitter electrode 21 is provided between the fifth portion 13a and the ninth portion 13c. The second region 21b of the emitter electrode 21 is provided between the sixth portion 13b and the ninth portion 13c.

The seventh portion 11c of the first gate wiring 11, the eighth portion 12c of the second gate wiring 12, and the ninth portion 13c of the third gate wiring 13 are so-called gate fingers.

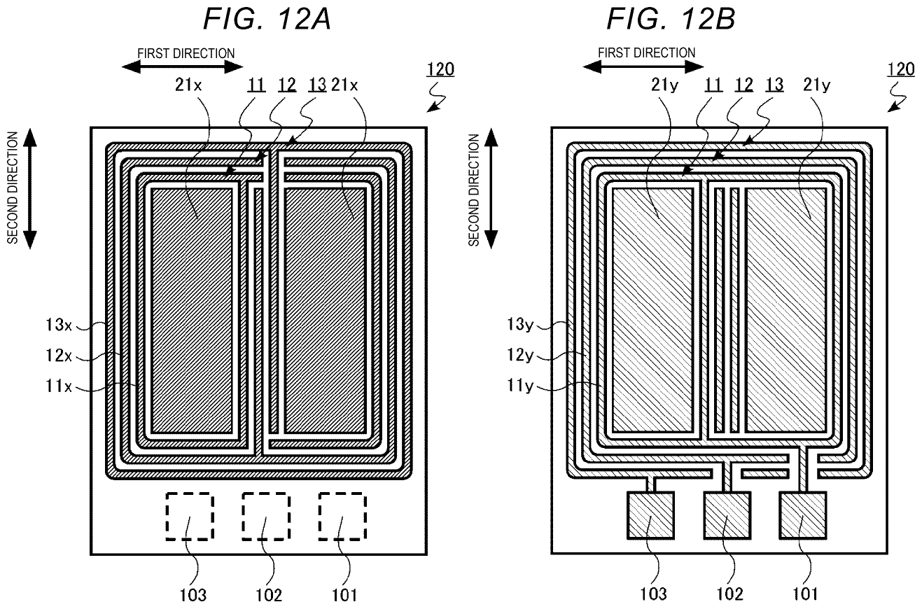

FIGS. 12A and 12B are schematic views of a semiconductor device according to the second modification example of the first embodiment. FIGS. 12A and 12B are views corresponding to FIGS. 6A and 6B of the first embodiment.

FIG. 12A shows a layout pattern of the first lower metal layer 11x of the first gate wiring 11, the second lower metal layer 12x of the second gate wiring 12, the third lower metal layer 13x of the third gate wiring 13, and the fourth lower metal layer 21x of the emitter electrode 21. FIG. 12B shows a layout pattern of the first upper metal layer 11y of the first gate wiring 11, the second upper metal layer 12y of the second gate wiring 12, the third upper metal layer 13y of the third gate wiring 3, and the fourth upper metal layer 21y of the emitter electrode 21.

FIG. 12B also shows a layout pattern of the first gate electrode pad 101, the second gate electrode pad 102, and the third gate electrode pad 103, which are formed of the second material identical to the first upper metal layer 11y, the second upper metal layer 12y, the third upper metal layer 13y, and the fourth upper metal layer 21y.

According to the IGBT 120 of the second modification example of the first embodiment, the electrical resistance of the gate wiring can be reduced even in a case where the gate wiring includes the gate finger, as in the IGBT 100 of the first embodiment.

### Third Modification Example

A semiconductor device of a third modification example of the first embodiment is different from the semiconductor device of the first embodiment in that the first gate wiring does not surround the first electrode and the second gate wiring does not surround the first electrode.

The semiconductor device according to the third modification example of the first embodiment is an IGBT 130.

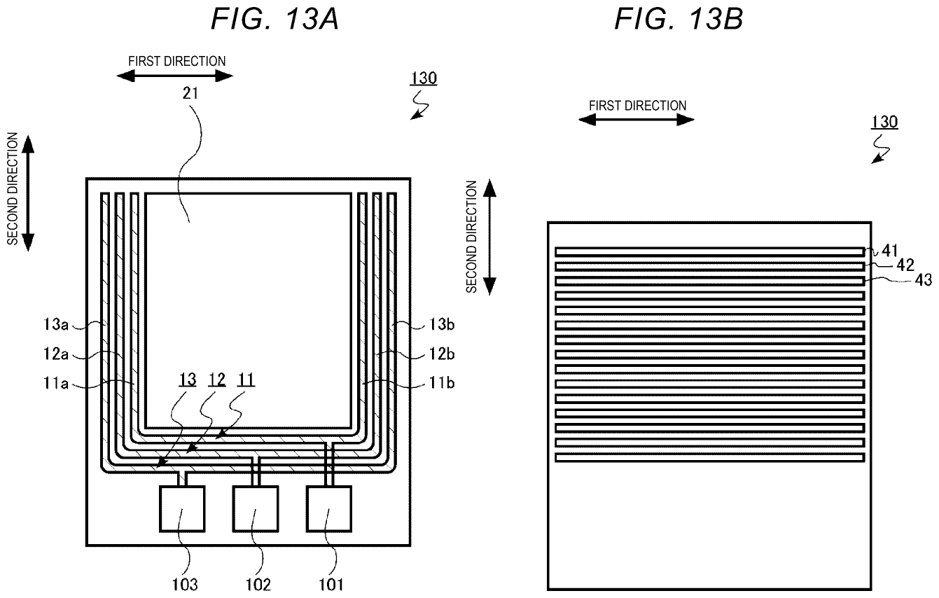

FIGS. 13A and 13B are schematic views of the semiconductor device according to the third modification example of the first embodiment. FIGS. 13A and 13B are views corresponding to FIGS. 1A and 1B of the first embodiment.

The first gate wiring 11 does not surround the emitter electrode 21. In addition, the second gate wiring 12 does not surround the emitter electrode 21. In addition, the third gate wiring 13 does not surround the emitter electrode 21.

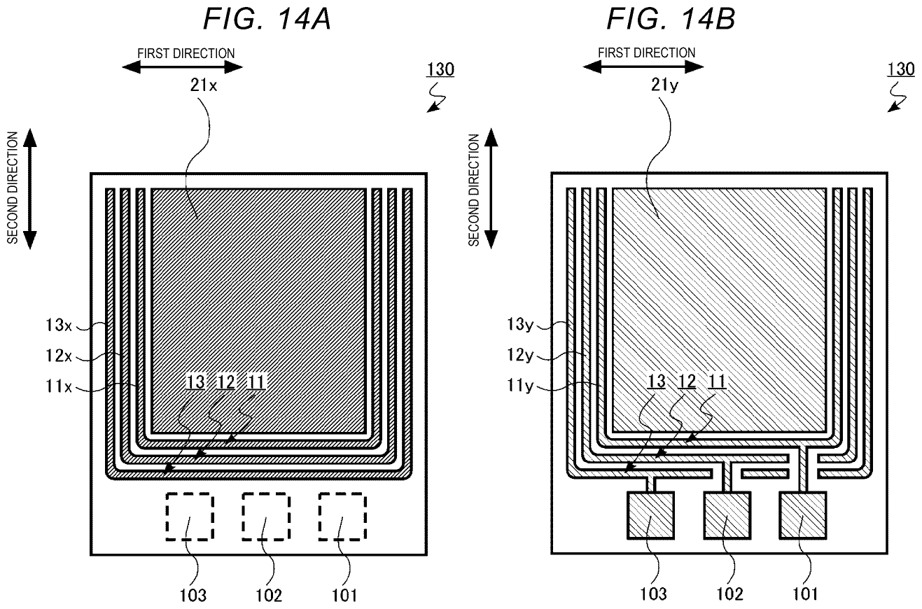

FIG. 14A and FIG. 14B are schematic views of the semiconductor device according to the third modification example of the first embodiment. FIGS. 13A and 13B are views corresponding to FIGS. 6A and 6B of the first embodiment.

FIG. 14A shows a layout pattern of the first lower metal layer 11x of the first gate wiring 11, the second lower metal layer 12x of the second gate wiring 12, the third lower metal layer 13x of the third gate wiring 13, and the fourth lower metal layer 21x of the emitter electrode 21. FIG. 14B shows a layout pattern of the first upper metal layer 11y of the first gate wiring 11, the second upper metal layer 12y of the second gate wiring 12, the third upper metal layer 13y of the third gate wiring 13, and the fourth upper metal layer 21y of the emitter electrode 21.

FIG. 14B also shows a layout pattern of the first gate electrode pad 101, the second gate electrode pad 102, and the third gate electrode pad 103, which are formed of the second material identical to the first upper metal layer 11y, the second upper metal layer 12y, the third upper metal layer 13y, and the fourth upper metal layer 21y.

According to the IGBT 130 of the third modification example of the first embodiment, the electrical resistance of the gate wiring can be reduced as in the IGBT 100 of the first embodiment.

As described above, according to the first embodiment and the modification example, a semiconductor device in which the electrical resistance of a gate wiring can be reduced can be provided.

### Second Embodiment

A semiconductor device according to a second embodiment includes a semiconductor layer having a first surface and a second surface facing the first surface and including a plurality of first trenches provided on a first surface side and extending in a first direction parallel to the first surface, a plurality of second trenches provided on the first surface side and extending in the first direction, and a plurality of third trenches provided on the first surface side and extending in the first direction; a first electrode provided on the first surface side of the semiconductor layer; a second electrode provided on a second surface side of the semiconductor layer; a first gate electrode provided in the first trench; a second gate electrode provided in the second trench; a third gate electrode provided in the third trench; a first gate wiring provided on the first surface side of the semiconductor layer, including a first upper metal layer and a first lower metal layer provided between the first upper metal layer and the first surface, including a first portion extending in a second direction parallel to the first surface and perpendicular to the first direction and a second portion extending in the second direction and having the first electrode provided between the first portion and the second portion, and electrically connected to the first gate electrode; a second gate wiring provided on the first surface side of the semiconductor layer, including a third portion extending in the second direction and a fourth portion extending in the second direction and having the first electrode provided between the third portion and the fourth portion, and electrically connected to the second gate electrode; a third gate wiring provided on the first surface side of the semiconductor layer, including a third upper metal layer and a third lower metal layer provided between the third upper metal layer and the first surface, including a fifth portion extending in the second direction and a sixth portion extending in the second direction and having the first electrode provided between the fifth portion and the sixth portion, and electrically connected to the third gate electrode; a first gate electrode pad provided on the first surface side of the semiconductor layer and electrically connected to the first gate wiring; a second gate electrode pad provided on the first surface side of the semiconductor layer and electrically connected to the second gate wiring; and a third gate electrode pad provided on the first surface side of the semiconductor layer and electrically connected to the third gate wiring. The first portion is provided between the third portion and the first electrode, and the third portion is provided between the fifth portion and the first electrode. A first distance in the first direction between the first upper metal layer of the first portion and the third upper metal layer of the fifth portion is smaller than a first width in the first direction of the third portion. The semiconductor device of the second embodiment is different from the semiconductor device of the first embodiment in that a first distance in the first direction between the upper metal layer of the first portion of the first gate wiring and the upper metal layer of the first portion of the third gate wiring is smaller than a first width of the first portion of the second gate wiring in the first direction.

The semiconductor device of the second embodiment is a trench-gate type IGBT 200 including the gate electrode in the trench formed in the semiconductor layer. The IGBT 200 is an IGBT having three gates that can be controlled independently and can be driven by the triple gate.

The IGBT 200 of the second embodiment includes a semiconductor layer 10, a first gate wiring 11, a second gate wiring 12, a third gate wiring 13, a first contact part 16, a second contact part 17, a third contact part 18, an emitter electrode 21 (first electrode), a collector electrode 22 (second electrode), a gate insulating film 23, a first gate electrode 31, a second gate electrode 32, a third gate electrode 33, a first interlayer insulating layer 36, a second interlayer insulating layer 37, a first gate electrode pad 101, a second gate electrode pad 102, and a third gate electrode pad 103.

The first gate wiring 11 includes a first portion 11a and a second portion 11b. The first gate wiring 11 includes a first lower metal layer 11x and a first upper metal layer 11y.

The second gate wiring 12 includes a third portion 12a and a fourth portion 12b.

The third gate wiring 13 includes a fifth portion 13a and a sixth portion 13b. The third gate wiring 13 includes a third lower metal layer 13x and a third upper metal layer 13y.

The emitter electrode 21 includes a fourth lower metal layer 21x and a fourth upper metal layer 21y.

A first gate trench 41 (first trench), a second gate trench 42 (second trench), a third gate trench 43 (third trench), a collector region 51, a drift region 52, a base region 53, an emitter region 54, and a contact region 55 are provided in the semiconductor layer 10.

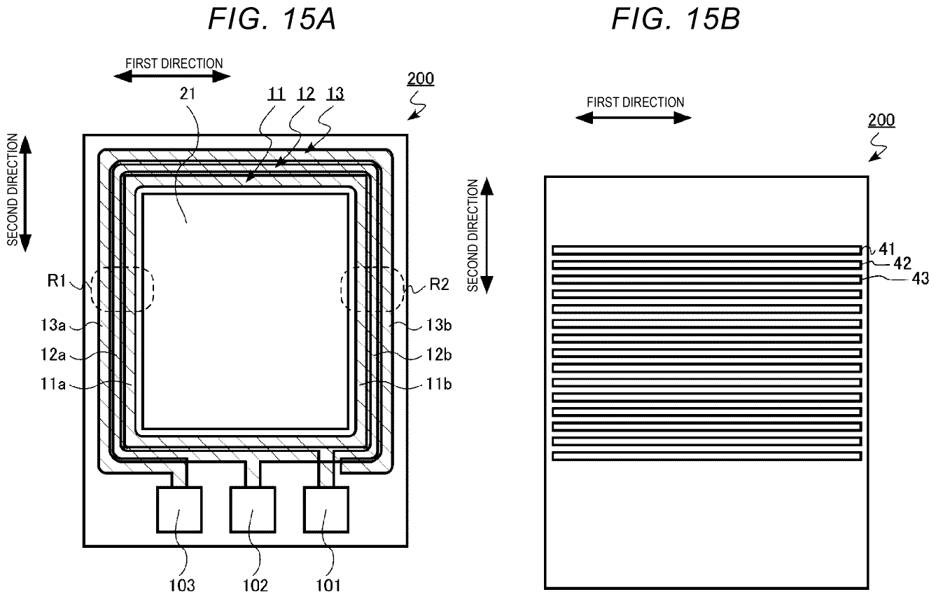

FIGS. 15A and 15B are schematic views of the semiconductor device of the second embodiment. FIG. 15A shows a layout pattern of the first gate wiring 11, the second gate wiring 12, the third gate wiring 13, the first gate electrode pad 101, the second gate electrode pad 102, the third gate electrode pad 103, and the emitter electrode 21. FIG. 15B shows a layout pattern of the first gate trench 41, the second gate trench 42, and the third gate trench 43.

As shown in FIG. 15A, the first gate wiring 11 is connected to the first gate electrode pad 101. The first gate wiring 11 is electrically and physically connected to the first gate electrode pad 101. The first portion 11a of the first gate wiring 11 extends in the second direction. The second portion 11b of the first gate wiring 11 extends in the second direction. The emitter electrode 21 is provided between the first portion 11a and the second portion 11b. The first gate wiring 11 surrounds the emitter electrode 21.

As shown in FIG. 15A, the second gate wiring 12 is connected to the second gate electrode pad 102. The second gate wiring 12 is electrically and physically connected to the second gate electrode pad 102. The third portion 12a of the second gate wiring 12 extends in the second direction. The fourth portion 12b of the second gate wiring 12 extends in the second direction. The emitter electrode 21 is provided between the third portion 12a and the fourth portion 12b. The second gate wiring 12 surrounds the emitter electrode 21.

The first portion 11a is provided between the third portion 12a and the emitter electrode 21. The second portion 11b is provided between the fourth portion 12b and the emitter electrode 21.

As shown in FIG. 15A, the third gate wiring 13 is connected to the third gate electrode pad 103. The third gate wiring 13 is electrically and physically connected to the third gate electrode pad 103. The fifth portion 13a of the third gate wiring 13 extends in the second direction. The sixth portion 13b of the third gate wiring 13 extends in the second direction. The emitter electrode 21 is provided between the fifth portion 13a and the sixth portion 13b.

The third portion 12a is provided between the fifth portion 13a and the emitter electrode 21. The fourth portion 12b is provided between the sixth portion 13b and the emitter electrode 21.

A part of the first gate wiring 11 and a part of the second gate wiring 12 overlap each other. A part of the second gate wiring 12 and a part of the third gate wiring 13 overlap each other.

As shown in FIG. 15B, the first gate trench 41, the second gate trench 42, and the third gate trench 43 extend in the first direction.

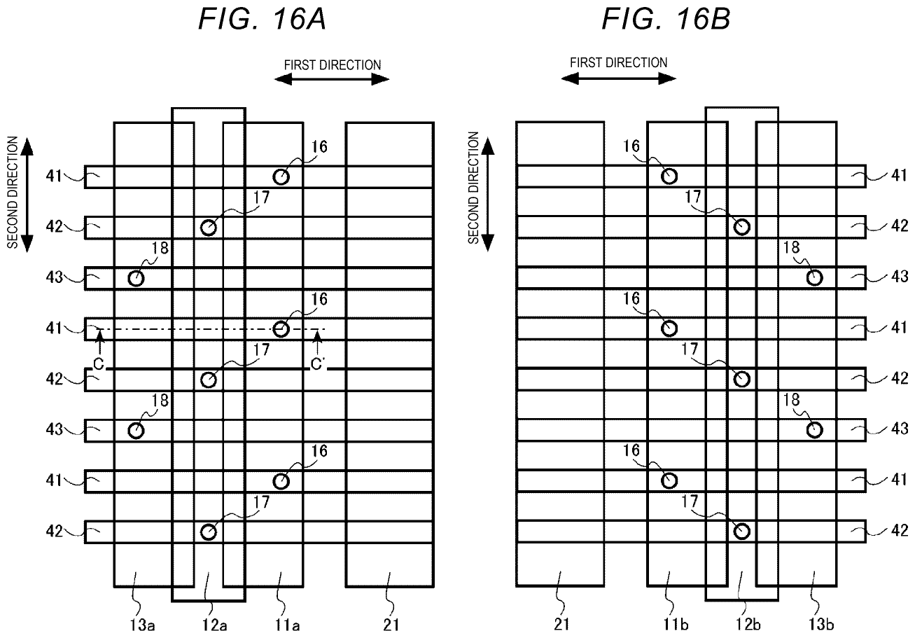

FIGS. 16A and 16B are schematic views of a part of the semiconductor device of the second embodiment. FIG. 16A is an enlarged view of the first region R1 shown in FIG. 15A. FIG. 16B is an enlarged view of the second region R2 shown in FIG. 15A.

FIGS. 16A and 16B show layout patterns of the first gate wiring 11, the second gate wiring 12, the third gate wiring 13, the first contact part 16, the second contact part 17, the third contact part 18, and the emitter electrode 21.

As shown in FIG. 16A, the first contact part 16 is provided at a position where the first portion 11a of the first gate wiring 11 and the first gate trench 41 intersect. At the first contact part 16, the first portion 11a is electrically and physically connected to the first gate electrode 31 provided in the first gate trench 41.

As shown in FIG. 16A, the second contact part 17 is provided at a position where the third portion 12a of the second gate wiring 12 and the second gate trench 42 intersect. At the second contact part 17, the third portion 12a is electrically and physically connected to the second gate electrode 32 provided in the second gate trench 42.

As shown in FIG. 16A, the third contact part 18 is provided at a position where the fifth portion 13a of the third gate wiring 13 and the third gate trench 43 intersect. At the third contact part 18, the fifth portion 13a is electrically and physically connected to the third gate electrode 33 provided in the third gate trench 43.

As shown in FIG. 16B, the first contact part 16 is provided at a position where the second portion 11b of the first gate wiring 11 and the first gate trench 41 intersect. At the first contact part 16, the second portion 11b is electrically and physically connected to the first gate electrode 31 provided in the first gate trench 41.

As shown in FIG. 16B, the second contact part 17 is provided at a position where the fourth portion 12b of the second gate wiring 12 and the second gate trench 42 intersect. At the second contact part 17, the fourth portion 12b is electrically and physically connected to the second gate electrode 32 provided in the second gate trench 42.

As shown in FIG. 16B, the third contact part 18 is provided at a position where the sixth portion 13b of the third gate wiring 13 and the third gate trench 43 intersect. At the third contact part 18, the sixth portion 13b is electrically and physically connected to the third gate electrode 33 provided in the third gate trench 43.

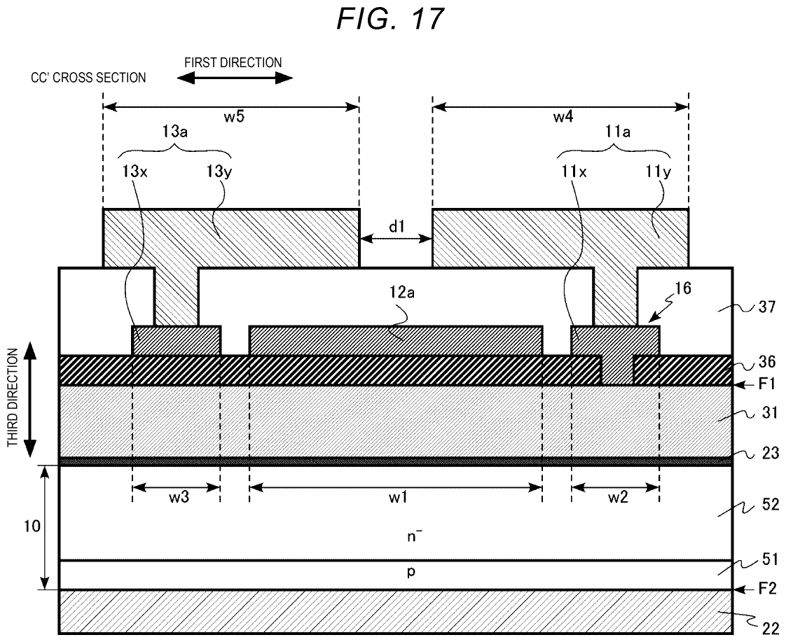

FIG. 17 is a schematic cross-sectional view of a part of the semiconductor device of the second embodiment. FIG. 17 is a cross-sectional view taken along the line CC′ of FIG. 16A.

The first gate wiring 11 is made of metal. The first gate wiring 11 includes the first lower metal layer 11x and the first upper metal layer 11y. The first lower metal layer 11x is provided between the first upper metal layer 11y and the first surface F1.

The second gate wiring 12 is made of a metal.

The third gate wiring 13 is made of a metal. The third gate wiring 13 includes the third lower metal layer 13x and the third upper metal layer 13y. The third lower metal layer 13x is provided between the third upper metal layer 13y and the first surface F1.

The first lower metal layer 11x, the second gate wiring 12, and the third lower metal layer 13x are formed of a first material. The first material is a metal. The first material of the first lower metal layer 11x, the second gate wiring 12, and the third lower metal layer 13x is the same as a first material of the fourth lower metal layer 21x of the emitter electrode 21.

The first upper metal layer 11y and the second upper metal layer 12y are formed of a second material. The second material is a metal. The second material of the first upper metal layer 11y and the third upper metal layer 13y is the same as the second material of the fourth upper metal layer 21y of the emitter electrode 21.

The first material and the second material are different metals. The first material is or comprises, for example, tungsten (W), molybdenum (Mo), or tantalum (Ta). The second material is or comprises, for example, aluminum (Al) or copper (Cu).

The first lower metal layer 11x, the second gate wiring 12, and the third lower metal layer 13x can be, for example, a stacked film of titanium, titanium nitride, and tungsten.

The first upper metal layer 11y and the third upper metal layer 13y can be, for example, a stacked film of titanium, titanium nitride, and aluminum.

The first lower metal layer 11x and the third lower metal layer 13x are electrically and physically connected to the first upper metal layer 11y and the third upper metal layer 13y, respectively.

Each of the first gate wiring 11 and the third gate wiring 13 has a stacked structure including two different metal layers.

As shown in FIG. 17, the second interlayer insulating layer 37 is provided, for example, between a part of the first lower metal layer 11x and a part of the first upper metal layer 11y. The second interlayer insulating layer 37 is provided, for example, between a part of the second gate wiring 12 and a part of the first upper metal layer 11y. The second interlayer insulating layer 37 is provided, for example, between a part of the second gate wiring 12 and a part of the third upper metal layer 13y. The second interlayer insulating layer 37 is provided, for example, between a part of the third lower metal layer 13x and a part of the third upper metal layer 13y.

As shown in FIG. 17, the first lower metal layer 11x of the first gate wiring 11 is connected to the first gate electrode 31 at the first contact part 16.

As shown in FIG. 17, a first distance (d1 in FIG. 17) in the first direction between the first upper metal layer 11y of the first portion 11a and the third upper metal layer 13y of the fifth portion 13a is smaller than a first width (w1 in FIG. 17) in the first direction of the third portion 12a of the second gate wiring.

As shown in FIG. 17, the first upper metal layer 11y of the first portion 11a and the third portion 12a overlap each other in the third direction. In addition, the third upper metal layer 13y of the fifth portion 13a and the third portion 12a overlap each other in the third direction.

As shown in FIG. 17, the first width w1 of the third portion 12a of the second gate wiring 12 in the first direction is wider than a second width (w2 in FIG. 17) of the first lower metal layer 11x of the first portion 11a of the first gate wiring 11 in the first direction. In addition, the first width w1 is wider than a third width (w3 in FIG. 17) of the third lower metal layer 13x of the fifth portion 13a of the third gate wiring 13 in the first direction.

As shown in FIG. 17, a fourth width (w4 in FIG. 17) of the first upper metal layer 11y of the first portion 11a of the first gate wiring 11 in the first direction is wider than the second width w2 of the first lower metal layer 11x of the first portion 11a in the first direction. In addition, a fifth width (w5 in FIG. 17) of the third upper metal layer 13y of the fifth portion 13a of the third gate wiring 13 in the first direction is wider than the third width w3 of the third lower metal layer 13x of the fifth portion 13a in the first direction.

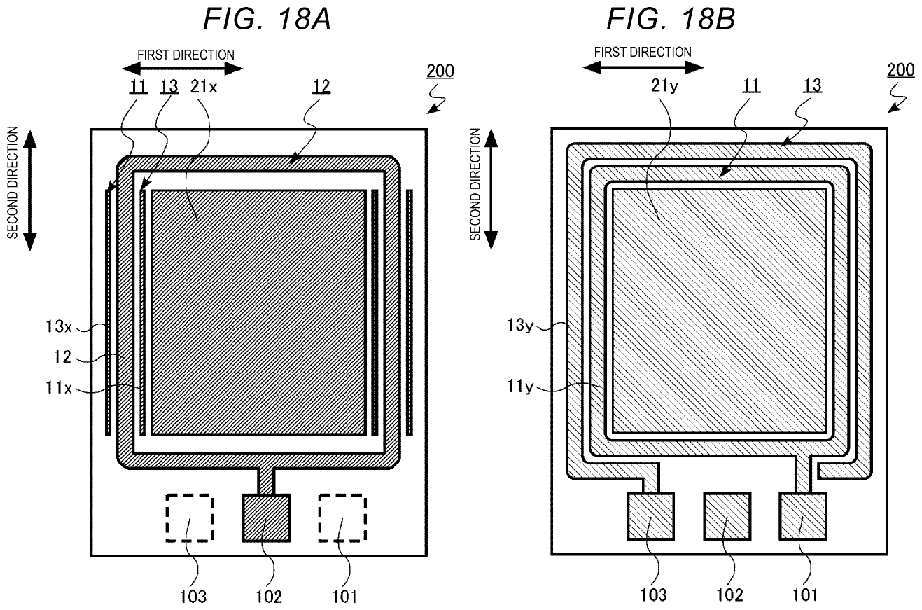

FIG. 18A and FIG. 18B are schematic views of the semiconductor device of the second embodiment. FIGS. 18A and 18B are views corresponding to FIGS. 6A and 6B of the first embodiment.

FIG. 18A shows a layout pattern of the first lower metal layer 11x, the second gate wiring 12, the third lower metal layer 13x, and the fourth lower metal layer 21x. FIG. 18B shows a layout pattern of the first upper metal layer 11y, the third upper metal layer 13y, and the fourth upper metal layer 21y.

A layout pattern of the second gate electrode pad 102 formed of the same first material as the first lower metal layer 11x, the second gate wiring 12, the third lower metal layer 13x, and the fourth lower metal layer 21x is also shown in FIG. 18A.

In addition, FIG. 18B also shows a layout pattern of the first gate electrode pad 101, the second gate electrode pad 102, and the third gate electrode pad 103, which are formed of the second material identical to the first upper metal layer 11y, the third upper metal layer 13y, and the fourth upper metal layer 21y.

As shown in FIG. 18A, the second gate wiring 12 surrounds the fourth lower metal layer 21x of the emitter electrode 21. The second gate wiring 12 surrounds the emitter electrode 21. The second gate wiring 12 is annular in a plane parallel to the first surface F1.

As shown in FIG. 18B, the first upper metal layer 11y surrounds the fourth upper metal layer 21y. The first upper metal layer 11y surrounds the emitter electrode 21. The first upper metal layer 11y is annular in a plane parallel to the first surface F1.

Next, an operation and an effect of the semiconductor device of the second embodiment will be described.

The IGBT 200 of the second embodiment can achieve both a reduction in on-resistance and a reduction in switching loss by triple gate driving, for example.

In the IGBT 200 of the second embodiment, at least a part of the first gate wiring 11 has a stacked structure including the first lower metal layer 11x and the first upper metal layer 11y. In addition, at least a part of the third gate wiring 13 has a stacked structure including the third lower metal layer 13x and the third upper metal layer 13y. Therefore, the electrical resistance per unit length of the gate wiring can be reduced.

According to the IGBT 200 of the second embodiment, for example, it is possible to increase the speed of the operation of the IGBT 200 by reducing the electrical resistance of the gate wiring.

In addition,, in the IGBT 200 of the second embodiment, as shown in FIG. 17, the first distance (d1 in FIG. 17) in the first direction between the first upper metal layer 11y of the first portion 11a and the third upper metal layer 13y of the fifth portion 13a is smaller than the first width (w1 in FIG. 17) in the first direction of the third portion 12a of the second gate wiring. Therefore, the first upper metal layer 11y of the first portion 11a and the third portion 12a of the second gate wiring 12 overlap each other in the third direction. In addition, the third upper metal layer 13y of the fifth portion 13a and the third portion 12a overlap each other in the third direction.

By disposing three gate wirings extending in the second direction in a stacked manner, a width in the first direction of the region in which the gate wirings are provided can be reduced. Therefore, for example, the chip size of the IGBT 200 can be reduced.

### First Modification Example

The semiconductor device according to the first modification example of the second embodiment is different from the semiconductor device according to the second embodiment in that the second gate wiring includes a lower metal layer and an upper metal layer.

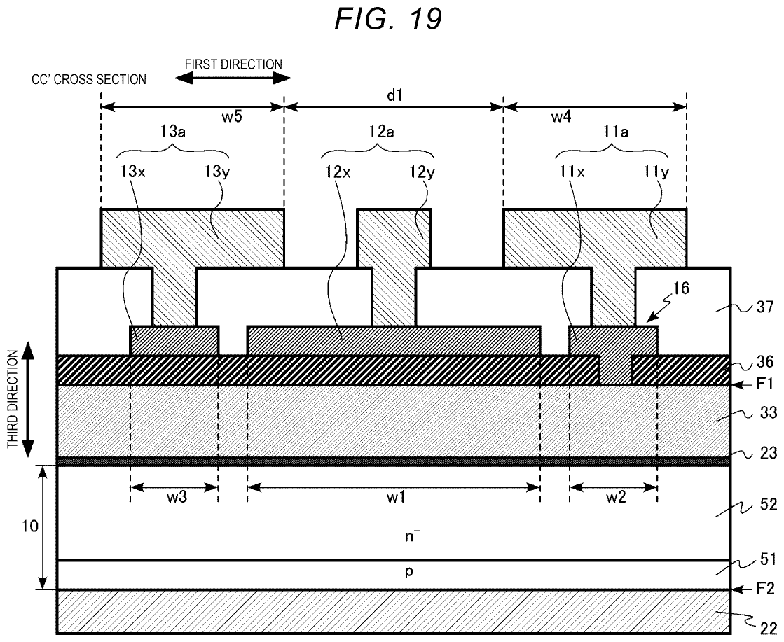

FIG. 19 is a schematic cross-sectional view of a part of a semiconductor device according to the first modification example of the second embodiment. FIG. 19 is a view corresponding to FIG. 17 of the second embodiment.

The second gate wiring 12 includes a second lower metal layer 12x and a second upper metal layer 12y. The second lower metal layer 12x is provided between the second upper metal layer 12y and the first surface F1.

The first lower metal layer 11x, the second lower metal layer 12x, and the third lower metal layer 13x are formed of a first material. The first material is a metal. The first material of the first lower metal layer 11x, the second lower metal layer 12x, and the third lower metal layer 13x is the same as the first material of the fourth lower metal layer 21x of the emitter electrode 21.

The first upper metal layer 11y, the second upper metal layer 12y, and the third upper metal layer 13y are formed of a second material. The second material is a metal. The second material of the first upper metal layer 11y, the second upper metal layer 12y, and the third upper metal layer 13y is the same as the second material of the fourth upper metal layer 21y of the emitter electrode 21.

The first material and the second material are different metals. The first material is or comprises, for example, tungsten (W), molybdenum (Mo), or tantalum (Ta). The second material is or comprises, for example, aluminum (Al) or copper (Cu).

The first lower metal layer 11x, the second lower metal layer 12x, and the third lower metal layer 13x can be, for example, a stacked film of titanium, titanium nitride, and tungsten.

The first upper metal layer 11y, the second upper metal layer 12y, and the third upper metal layer 13y can be, for example, a stacked film of titanium, titanium nitride, and aluminum.

The first lower metal layer 11x, the second lower metal layer 12x, and the third lower metal layer 13x are electrically and physically connected to the first upper metal layer 11y, the second upper metal layer 12y, and the third upper metal layer 13y, respectively.

Each of the first gate wiring 11, the second gate wiring 12, and the third gate wiring 13 has a stacked structure including two different metal layers.

As shown in FIG. 19, the first distance (d1 in FIG. 19) in the first direction between the first upper metal layer 11y of the first portion 11a of the first gate wiring 11 and the third upper metal layer 13y of the fifth portion 13a of the third gate wiring 13 is smaller than the first width (w1 in FIG. 19) in the first direction of the second lower metal layer 12x of the third portion 12a of the second gate wiring.

As shown in FIG. 19, the first upper metal layer 11y of the first portion 11a and the second lower metal layer 12x of the third portion 12a overlap each other in the third direction. In addition, the third upper metal layer 13y of the fifth portion 13a of the third gate wiring 13 and the second lower metal layer 12x of the third portion 12a of the second gate wiring 12 overlap each other in the third direction.

As shown in FIG. 19, the first width w1 of the second lower metal layer 12x of the third portion 12a in the first direction is wider than the second width (w2 in FIG. 19) of the first lower metal layer 11x of the first portion 11a in the first direction. In addition, the first width w1 is wider than the third width (w3 in FIG. 19) of the third lower metal layer 13x of the fifth portion 13a of the third gate wiring in the first direction.

As shown in FIG. 19, the fourth width (w4 in FIG. 19) of the first upper metal layer 11y of the first portion 11a of the first gate wiring 11 in the first direction is wider than the second width w2 of the first lower metal layer 11x of the first portion 11a in the first direction. In addition, the fifth width (w5 in FIG. 19) of the third upper metal layer 13y of the fifth portion 13a of the third gate wiring 13 in the first direction is wider than the third width w3 of the third lower metal layer 13x of the fifth portion 13a in the first direction.

According to the IGBT of the second modification example of the second embodiment, the electrical resistance of the gate wiring can be reduced as in the IGBT 200 of the second embodiment. In particular, by forming the second gate wiring stacked structure, the electrical resistance of the second gate wiring can be reduced.

As described above, it is possible to provide a semiconductor device in which the electrical resistance of the gate wiring is reduced.

Although IGBTs having three gates that can be independently controlled are described as an example, an IGBT having two gates that can be independently controlled may be used in other examples. In such a case, the number of individual gate wirings would be two, and a configuration in which the third gate wiring of the first embodiment or the like is removed can be adopted. In addition, the IGBT may have a configuration in which four or more gates are independently controllable. In such a case, the number of individual gate wirings would be four or more, and a configuration in which a fourth gate wiring (and etc.) is provided outside the third gate wiring of the first embodiment or the like can be adopted.

In the first embodiment or the second embodiment, the described sequence order of each trench and the proportion of the number of each trench are optional, and embodiments are not necessarily limited to the sequence order and the proportion of the number of the first embodiment or the second embodiment.

A trench in which the conductive layer inside the trench is not electrically connected to the gate wiring may also be provided in the semiconductor device. For example, a trench in which the conductive layer inside the trench is electrically connected to the emitter electrode may be provided.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor layer having a first surface and a second surface opposite the first surface;
a plurality of first trenches extending into the semiconductor layer from a first surface side and extending lengthwise in a first direction parallel to the first surface;
a plurality of second trenches extending into the semiconductor layer from the first surface side and extending lengthwise in the first direction;
a first electrode on the first surface side of the semiconductor layer;
a second electrode on a second surface side of the semiconductor layer;
a first gate electrode in each first trench;
a second gate electrode in each second trench;
a first gate wiring on the first surface side of the semiconductor layer and electrically connected to the first gate electrode, the first gate wiring including a first upper metal layer and a first lower metal layer, the first lower metal layer being between the first upper metal layer and the first surface, a first portion of the first gate wiring extending in a second direction perpendicular to the first direction and parallel to the first surface, a second portion of the first gate wiring extending in the second direction, the first electrode being between the first portion and the second portion;
a second gate wiring on the first surface side of the semiconductor layer and electrically connected to the second gate electrode, the second gate wiring including a second upper metal layer and a second lower metal layer, the second lower metal layer being between the second upper metal layer and the first surface, a third portion of the second gate wiring extending in the second direction, a fourth portion of the second gate wiring extending in the second direction, the first electrode being between the third portion and the fourth portion;
a first gate electrode pad on the first surface side of the semiconductor layer and electrically connected to the first gate wiring; and
a second gate electrode pad on the first surface side of the semiconductor layer and electrically connected to the second gate wiring, wherein
the first portion of the first gate wiring is between the first electrode and the third portion of the second gate wiring,
the second portion of the first gate wiring is between the first electrode and the fourth portion of the second gate wiring,
the first gate wiring and the second gate wiring cross at a first position, and
at the first position, the first lower metal layer and the second upper metal layer are not present or the first upper metal layer and the second lower metal layer are not.

2. The semiconductor device according to claim 1, wherein
the first portion is connected to the first gate electrode where the first portion and the first trench intersect,
the second portion is connected to the first gate electrode where the second portion and the first trench intersect,
the third portion is connected to the second gate electrode where the third portion and the second trench intersect, and
the fourth portion is connected to the second gate electrode where the fourth portion and the second trench intersect.

3. The semiconductor device according to claim 1, wherein
the first gate wiring surrounds the first electrode, and
the second gate wiring surrounds the first electrode.

4. The semiconductor device according to claim 1, wherein
the first lower metal layer surrounds the first electrode, and
the second lower metal layer surrounds the first electrode.

5. The semiconductor device according to claim 1, further comprising:
a plurality of third trenches extending into the semiconductor layer from the first surface side and extending lengthwise in the first direction;
a third gate electrode in each third trench;
a third gate wiring on the first surface side of the semiconductor layer and electrically connected to the third gate electrode, the third gate wiring including a third upper metal layer and a third lower metal layer, the third lower metal layer being between the third upper metal layer and the first surface, a fifth portion of the third gate wiring extending in the second direction, a sixth portion of the third gate wiring extending in the second direction, the first electrode being between the fifth portion and the sixth portion; and
a third gate electrode pad on the first surface side of the semiconductor layer and electrically connected to third gate wiring, wherein
the first gate wiring and the third gate wiring cross at a second position, and
at the second position, the first lower metal layer and the third upper metal layer are not present or the first upper metal layer and the third lower metal layer are not present.

6. The semiconductor device according to claim 5, wherein
the fifth portion is connected to the third gate electrode where the fifth portion and the third trench intersect, and
the sixth portion is connected to the third gate electrode where the sixth portion and the third trench intersect.

7. The semiconductor device according to claim 5, wherein
the second gate wiring and the third gate wiring intersect at a third position, and
at the third position, the second lower metal layer and the third upper metal layer are not present or the second upper metal layer and the third lower metal layer are not present.

8. The semiconductor device according to claim 1, wherein
the first lower metal layer and the second lower metal layer comprise tungsten, and
the first upper metal layer and the second upper metal layer comprise aluminum.

9. The semiconductor device according to claim 1, wherein an insulating layer is between the first gate wiring and the second gate wiring at the first position.

10. The semiconductor device according to claim 1, wherein
the first electrode includes a fourth upper metal layer and a fourth lower metal layer between the fourth upper metal layer and the first surface,
the fourth lower metal layer, the first lower metal layer, and the second lower metal layer are made of the same material, and
the fourth upper metal layer, the first upper metal layer, and the second upper metal layer are made of the same material.

11. A semiconductor device, comprising:
a semiconductor layer having a first surface and a second surface opposite the first surface;
a plurality of first trenches extending into the semiconductor layer from a first surface side and extending lengthwise in a first direction parallel to the first surface;
a plurality of second trenches extending into the semiconductor layer from the first surface side and extending lengthwise in the first direction;
a plurality of third trenches extending into the semiconductor layer from the first surface side and extending lengthwise in the first direction;
a first electrode on the first surface side of the semiconductor layer;
a second electrode on a second surface side of the semiconductor layer;
a first gate electrode in each first trench;
a second gate electrode in each second trench;
a third gate electrode in each third trench;
a first gate wiring on the first surface side of the semiconductor layer and electrically connected to the first gate electrode, the first gate wiring including a first upper metal layer and a first lower metal layer, the first lower metal layer being between the first upper metal layer and the first surface, a first portion of the first gate wiring extending in a second direction perpendicular to the first direction and parallel to the first surface, a second portion of the first gate wiring extending in the second direction, the first electrode being between the first portion and the second portion;
a second gate wiring on the first surface side of the semiconductor layer and electrically connected to the second gate electrode, the second gate wiring including a second upper metal layer and a second lower metal layer, the second lower metal layer being between the second upper metal layer and the first surface, a third portion of the second gate wiring extending in the second direction, a fourth portion of the second gate wiring extending in the second direction, the first electrode being between the third portion and the fourth portion;
a third gate wiring on the first surface side of the semiconductor layer and electrically connected to the third gate electrode, the third gate wiring including a third upper metal layer and a third lower metal layer, the third lower metal layer being between the third upper metal layer and the first surface, a fifth portion of the third gate wiring extending in the second direction, a sixth portion of the third gate wiring extending in the second direction, the first electrode being between the fifth portion and the sixth portion;
a first gate electrode pad on the first surface side of the semiconductor layer and electrically connected to the first gate wiring;
a second gate electrode pad on the first surface side of the semiconductor layer and electrically connected to the second gate wiring; and
a third gate electrode pad on the first surface side of the semiconductor layer and electrically connected to the third gate wiring, wherein
the first portion of the first gate wiring is between the first electrode and the third portion of the second gate wiring,
the third portion of the second gate wiring is provided between the first electrode and the fifth portion of the third gate wiring, and
a first distance, in the first direction, between the first upper metal layer in the first portion and the third upper metal layer in the fifth portion is less than a first width of the third portion in the first direction.

12. The semiconductor device according to claim 11, wherein the second gate wiring surrounds the first electrode.

13. The semiconductor device according to claim 11, wherein
the first width is greater than a second width, in the first direction, of the first lower metal layer in the first portion, and
the first width is greater than a third width, in the first direction of the third lower metal layer in the fifth portion.

14. The semiconductor device according to claim 11, wherein
a fourth width, in the first direction, of the first upper metal layer in the first portion is greater than a second width, in the first direction, of the first lower metal layer in the first portion and
a fifth width, in the first direction, of the third upper metal layer in the fifth portion is greater than a third width, in the first direction, of the third lower metal layer in the fifth portion.

15. The semiconductor device according to claim 11, wherein
the first lower metal layer and the third lower metal layer comprise tungsten,
the first upper metal layer and the third upper metal layer comprise aluminum, and
the second gate wiring comprises tungsten.

16. The semiconductor device according to claim 11, wherein
the second gate wiring further includes a second upper metal layer and a second lower metal layer, and
the second lower metal layer is between the second upper metal layer and the first surface.

17. The semiconductor device according to claim 11, wherein
the first electrode includes a fourth upper metal layer and a fourth lower metal layer,
the fourth lower metal layer is between the fourth upper metal layer and the first surface,
the fourth lower metal layer, the first lower metal layer, and the third lower metal layer are made of the same material, and
the fourth upper metal layer, the first upper metal layer, and the third upper metal layer are made of the same material.

18. A insulated gate bipolar transistor device, comprising:
a semiconductor layer;
a first electrode on a first surface of the semiconductor layer;
a second electrode on a second surface of the semiconductor layer;
a plurality of first trenches extending from the first surface into the semiconductor layer in a direction orthogonal to the first surface and extending lengthwise in a first direction parallel to the first surface, the plurality of first trenches being spaced from each other in a second direction parallel to the first surface and perpendicular to the first direction;
a plurality of second trenches extending from the first surface into the semiconductor layer and extending lengthwise in the first direction, the plurality of second trenches being spaced from each other in the second direction;
a first gate electrode in each first trench;
a second gate electrode in each second trench;
a first gate wiring on a first surface side of the semiconductor layer and electrically connected to the first gate electrode, the first gate wiring including a first upper metal layer and a first lower metal layer, the first lower metal layer being between the first upper metal layer and the first surface, a first portion of the first gate wiring extending in the second direction, a second portion of the first gate wiring extending in the second direction, the first electrode being between the first portion and the second portion along the first direction; and
a second gate wiring on the first surface side of the semiconductor layer and electrically connected to the second gate electrode, the second gate wiring including a second upper metal layer and a second lower metal layer, the second lower metal layer being between the second upper metal layer and the first surface, a third portion of the second gate wiring extending in the second direction, a fourth portion of the second gate wiring extending in the second direction, the first electrode being between the third portion and the fourth portion along the first direction, wherein
the first portion of the first gate wiring is between the first electrode and the third portion of the second gate wiring in the first direction,
the second portion of the first gate wiring is between the first electrode and the fourth portion of the second gate wiring in the first direction,
the first gate wiring and the second gate wiring cross at a first position, and
at the first position, the first lower metal layer and the second upper metal layer are not present or the first upper metal layer and the second lower metal layer are not.

19. The insulated gate bipolar transistor device according to claim 18, wherein
the first gate wiring includes an annular portion that surrounds the first electrode in a plane parallel to the first surface, and
the second gate wiring includes an annular portion that surrounds the first electrode and the annular portion of the first gate wiring in a plane parallel to the first surface.

20. The insulated gate bipolar transistor device according to claim 19, further comprising:
a first gate electrode pad on the first surface side of the semiconductor layer and electrically connected to the first gate wiring via a linear portion extending in the second direction from the annular portion of the first gate wiring; and
a second gate electrode pad on the first surface side of the semiconductor layer and electrically connected to the second gate wiring via a linear portion extending in the second direction from the annular portion of the second gate wiring.
